(19) United States
(12) Patent Application Publication
(10) Pub. No.: US 2024/0266337 A1
(43) Pub. Date: Aug. 8, 2024

(54) SEMICONDUCTOR SENSOR DEVICE AND METHOD FOR MANUFACTURING A SEMICONDUCTOR SENSOR DEVICE

(71) Applicant: ams-OSRAM Asia Pacific Pte. Ltd., Singapore (SG)

(72) Inventors: Harald ETSCHMAIER, Graz (AT); Dan JACOBS, Hitzendorf (AT); Martin FACCINELLI, Graz (AT); Gerhard PEHARZ, Gleisdorf (AT)

(21) Appl. No.: 18/566,258

(22) PCT Filed: May 24, 2022
(86) PCT No.: PCT/SG2022/050347

§ 371 Date: Dec. 1, 2023

Related U.S. Application Data
(60) Provisional application No. 63/195,458, filed on Jun. 1, 2021.

(30) Foreign Application Priority Data
Jun. 15, 2021 (DE) 10 2021 115 461.8

(51) Int. Cl. H01L 25/16; H01L 23/29; H01L 23/31; H01L 23/495

(52) U.S. Cl. CPC H01L 25/167; H01L 23/291; H01L 23/293; H01L 23/3121; H01L 23/49575

(57) ABSTRACT

A semiconductor sensor device includes an integrated circuit body having a main surface. The semiconductor device also includes a photosensitive element arranged on the main surface. The photosensitive element has a sensing surface. The semiconductor device further includes a transparent structure arranged on the sensing surface. The semiconductor device additionally includes an emitter assembly arranged on the main surface at a distance from the photosensitive element. The semiconductor device also includes an opaque body arranged on a portion of the main surface that is free of the sensing surface and the emitter assembly. The top surfaces of the transparent structure, the emitter assembly and the opaque body form a common plane. The transparent structure is a glass body.

The present disclosure relates to a semiconductor sensor device and to a method for manufacturing a semiconductor sensor device.

In addition to their applications in mobile devices such as smartphones and tablet computers, semiconductor sensor devices are nowadays becoming increasingly relevant for wearable accessories such as smartwatches, in which e.g. ambient light sensors and proximity sensors are commonly integrated in addition to other sensor types such as microphones. One of the major selling propositions for semiconductor sensors in wearable applications is a small size since space in wearable gadgets is very limited, which poses a problem for the integration for multiple sensors.

Particularly for sensors that comprise a light emitter and receiver, such as optical proximity sensors, cross talk becomes a severe issue when decreasing the size of the sensor device, i.e. arranging the emitter and receiver components in close proximity to each other. Therein, cross talk can occur within the device as internal cross talk or within the system, typically referred to as external cross talk. Hence, due to the cross talk issue, present-day solutions are limited in terms of the minimal achievable sensor size.

It is an object to provide an improved concept of a semiconductor sensor device, which overcomes the limitations of present-day solutions.

This object is achieved by the subject-matter of the independent claims. Further developments and embodiments are described in the dependent claims.

The improved concept is based on the idea of overmolding a sensor assembly with an opaque compound, wherein the sensor assembly comprises a transparent structure, such as a glass body, which is arranged on a photosensitive surface of an integrated circuit, and an emitter assembly that is likewise arranged on the integrated circuit. The transparent body, the opaque body and the emitter assembly are arranged such that their respective top surfaces form a common plane. In particular, the improved concept relies on a single molding step.

In particular, a semiconductor sensor device according to the improved concept comprises an integrated circuit body having a main surface and a photosensitive element that is arranged on the main surface, the photosensitive element having a sensing surface. The sensor device further comprises a transparent structure arranged on the sensing surface, an emitter assembly arranged on the main surface at a distance from the photosensitive element, and an opaque body arranged on a portion of the main surface that is free of the sensing surface and the emitter assembly. The top surfaces of the transparent body, the opaque body and the light emitter assembly form a common plane.

The integrated circuit body is for example a semiconductor substrate, such as a wafer or a chip substrate, that on or within a top surfaces comprises active and/or passive circuit elements forming an integrated circuit with a main surface. In particular, said integrated circuit comprises a photosensitive element, such as a photodiode, with a photosensitive sensing surface on the main surface, e.g. implemented as a p-n junction device that converts light into an electrical current. The integrated circuit further comprises means, e.g. a contact surface, on its main surface for electrically contacting an emitter assembly, e.g. an emitter die, such that an emitter of the emitter assembly can be operated by elements of the integrated circuit.

The transparent structure is a glass body, for example, that is arranged on the sensing surface in a manner such that the sensing surface is partially or completely covered by the transparent structure. In other words, a footprint of the transparent structure covers all of the sensing surface in some embodiments of the semiconductor sensing device. For example, the transparent structure is a borosilicate glass body, in particular a borosilicate glass 3.3 body. The transparent structure is in contact with the sensing surface, either directly or via a connecting element such as an adhesive, which likewise is transparent.

Transparent in this context refers to a wavelength range, in which the photosensitive element is configured to receive light. For example, the transparent structure is transparent in at least a portion of the visible spectrum and/or in the infrared regime, e.g. including 830 nm and/or 940 nm. Borosilicate glass 3.3 is characterized by a coefficient of expansion that is similar to that of silicon, a typical material for the integrated circuit body.

The emitter assembly is arranged on the aforementioned contact surface, for instance, at a distance from the photosensitive element, i.e. from the sensing surface, and comprises an emitter that is configured to emit light and be controlled via the integrated circuit. The emitter emits light at a wavelength range that corresponds to a sensitivity range of the photosensitive element. For example, the emitter emits light in at least a portion of the visible spectrum and/or in the infrared regime, e.g. including 830 nm and/or 940 nm. For example, the emitter assembly comprises a VCSEL die having a vertical-cavity surface-emitting laser, VCSEL. For example, the VCSEL die comprises a backside emitting VCSEL structure. Alternatively or in addition, the emitter assembly comprises an LED die having a light-emitting diode, LED.

The opaque body is a mold compound, for example, that covers the main surface in portions that are free the sensing surface and the emitter assembly. In other words, the main surface is overmolded by the opaque body, which means that the opaque body fills the space between the transparent structure and the emitter assembly. In some embodiments, the opaque body can cover all portions of the main surface that are free of the sensing surface and the emitter assembly. This way, not only cross-talk between emitter and receiver, i.e. the photosensitive element, is prevented, but also a protection of the integrated circuit is achieved. Furthermore, background signals due to stray light is significantly reduced.

The opaque body can be a polymer mold compound, in particular formed from an epoxy. Opaque in this context refers to the aforementioned wavelength ranges, in which the photosensitive element is configured to receive light and the emitter is configured to emit light. For example, the opaque body is opaque in at least a portion of the visible spectrum and/or in the infrared regime, e.g. including 830 nm and/or 940 nm. For example, the opaque body is configured to absorb light within said wavelength range.

The opaque body can be formed by means of a float mold, in which a float mold tool is brought in contact with the top surface of the emitter die and the transparent body. The mold compound is then injected in the space between the tool and the assembly, such that the top surface of the emitter die and the transparent body remain exposed. In particular, the compound fills the gap between these components. Finally, the mold compound is cured.

The opaque body is shaped such that top surfaces of the transparent body, the opaque body and the light emitter assembly form a common plane. In other words, only the top surfaces of the transparent structure and the emitter assembly are exposed while other portions of said elements are covered or surrounded by the opaque body. This way, there is no direct optical path from the emitter to the sensing surface of the photosensitive element as at least a portion of the opaque body is arranged in between these elements on the optical path. The common plane can be parallel to the main surface.

A parallel or at least substantially parallel common plane with respect to the main surface further ensures that cross-talk is significantly reduced and thus prevented. Furthermore, a parallel common plane means that the top surfaces of the transparent body and the emitter are orthogonal or at least substantially orthogonal to the emitted and received light, hence reducing optical losses due to non-orthogonal reflectivity.

A semiconductor sensor device according to the improved concept enables a highly integrated package for a proximity sensor, for instance, in which light emitted by the emitter assembly is reflected from an object that is located at a distance from the sensor device back to the photosensitive element of the sensor device. Therein, cross talk, both internal and external, is efficiently prevented due to the opaque body leaving only top surfaces of the transparent body and the emitter assembly exposed.

In some embodiments, the semiconductor sensor device further comprises a substrate body or a leadframe that is bonded to a surface of the integrated circuit body opposite the main surface.

Said substrate body or leadframe can comprise additional circuitry for operating the sensing device. Electrical connections between the integrated circuit and the substrate body or leadframe can be established by means of wire bonding, for instance.

In some embodiments, a transparent adhesive is arranged between the photosensitive element and the transparent structure.

An optically transparent adhesive can be applied to the sensing surface in order to establish and/or promote adhesion of the transparent body to the main surface. Analogous to the above, transparent in this context refers to a sensing and emitting wavelength of the sensing device.

In some embodiments, the transparent structure comprises an optical filter, in particular a bandpass filter and/or an interference filter.

For example, the transparent body is coated at or near its top surface for realizing an interference filter or a dichroic filter. This way, the light that is received by the sensing surface of the photosensitive element can be restricted to a wavelength range that is narrow relative to a sensitivity range of the photosensitive element. This way, background signals due to ambient light and/or stray light can be prevented by rendering the sensing device sensitive to substantially only its operating wavelength range. Said filters can be characterized by an angle-dependent transmissivity such that the light received by the sensing surface can be further restricted to exclude unwanted light.

In some embodiments, a distance between the sensing surface and the emitter assembly is less than 500 μm, in particular less than 300 μm.

A sensing device according to the improved concept allows for the arrangement of the emitter die within 200-300 μm of the sensing surface. This in turn enables a highly integrated package for a sensing device, e.g. used as a proximity sensor. Such a structure not only reduces size and cost but also significantly improves cross-talk performance and reliability compared to conventional solutions.

In some embodiments, a footprint of the emitter assembly is smaller than 40,000 μm².

In some embodiments, a footprint of the sensing surface is smaller than 40,000 μm².

In some embodiments, a footprint of the semiconductor sensor device is smaller than 3 mm², in particular smaller than 2 mm².

The aforementioned dimensions allow for applications in wearable devices, in which space for components is extremely limited posing a problem particularly for the integration of multiple sensors. Moreover, it is well-known that cross-talk between emitter and receiver in a sensing device limits the performance of the sensor and that the cross-talk increases in severity the smaller the sensor device is engineered. However, the improved concept solves the cross-talk issue efficiently by means of the opaque body that is applied in a single molding step such that these small dimensions can be achieved and cross-talk, internal and external, can be efficiently reduced. Additionally, the dimensions of the sensing device, particularly the small distance between emitter die and sensing surface, reduce the size of the required system aperture.

In some embodiments, the semiconductor sensor device further comprises a further photosensitive element arranged on the main surface at a distance from the photosensitive element, the further photosensitive element having a further sensing surface, wherein the transparent structure is arranged on the sensing surface and on the further sensing surface.

For example, a first photosensitive element can be configured to receive light that is emitted by the emitter. The sensitivity of this photosensitive element can be restricted to a wavelength or wavelength range that includes light that is emitted by the emitter as described above. The further photosensitive element can be configured to receive light in a wavelength range that is different from that of the first photosensitive element. For example, the further photosensitive element is sensitive to the visible domain and implements an ambient light sensing functionality of the sensing device, while the first photosensitive element implements the aforementioned proximity sensing that is based on light that is emitted by the receiver and reflected from an object or a scene such as a body part of a user of the sensing device or a device that includes a sensing device according to the improved concept.

The aforementioned object is further solved by a proximity sensor assembly comprising a semiconductor sensor device according to one of the embodiments described above, wherein the photosensitive element is configured to capture light that is emitted from the emitter assembly and reflected from an object located in a proximity of the proximity sensor.

A proximity sensor according to the improved concept can be conveniently employed in mobile devices such as smartphones but also in wearable gadgets such as smartwatches. One of the major selling propositions for proximity sensors in wearable applications is a small size due to the very limited space in these devices. The improved concept enables a sensor device of significantly reduced dimensions compared to existing solutions while preventing any significant cross-talk between emitter and receiver that otherwise would be expected for a sensor with these dimensions.

Specific applications include a touch sensing application in wireless earbuds or wearable products. Therein, such a sensor detects if the product is being worn or not, or if it is properly worn, and enables the system to react accordingly, e.g. by switching power on or off automatically in order to save power. Alternatively or in addition, a detection can be implemented for determining whether the device is placed on a wireless charger, for example, such that a charging process is automatically enabled.

A second exemplary application is a combined proximity and ambient light sensor (ALS) for use in mobile phones. There, a sensor needs to be small enough in terms of its footprint in order to fit into the typically very small space in a corner of the bezel. In particular, the small dimensions of a sensor according to the improved concept enable a placement near the surface of a phone where its performance is significantly enhanced compared to larger sensor devices that need to be placed distant below the surface of the phone in a narrow opening or behind the display. In both cases, ALS performance is severely compromised, while in the case of a placement behind the display this is only possible with expensive OLED displays. This present disclosure, however, due to its small form factor enables enhanced performance at lower manufacturing costs.

The aforementioned object is further solved by a method for manufacturing a semiconductor sensor device. The method comprises providing an integrated circuit body having a main surface, arranging a photosensitive element with a sensing surface onto the main surface, and arranging a transparent structure on the sensing surface. The method further comprises arranging an emitter assembly on the main surface at a distance from the photosensitive element, and arranging an opaque body on a portion of the main surface that is free of the sensing surface and the emitter assembly. Therein, top surfaces of the transparent structure, the opaque body and the light emitter assembly form a common plane.

In some embodiments, arranging the transparent structure is implemented via gluing said transparent structure to the sensing surface, and arranging the opaque body is implemented via an injection molding process, in particular via a film assisted transfer molding process.

A multitude of integrated circuits containing a photosensitive area can be manufactured on a silicon wafer. The transparent structures, e.g. glass blocks, are glued with an optically transparent adhesive onto the wafer surface, covering the optically sensitive areas such as the sensing surface of the photosensitive element. The emitter dice are stacked onto the wafer surface and electrically connected to the integrated circuit. Therein, the thickness of the transparent structures and the emitter dice are such that the top surfaces are in the same plane substantially parallel or parallel to the wafer surface.

The individual integrated circuits can then be singulated in a sawing process. Multiple integrated circuits are bonded on a substrate or a leadframe. Electrical connections between the integrated circuits and substrate are established by wire bonding. A float mold tool is brought in contact with the top surface of the emitter and the transparent structure. A compliant polymer film on the tool can used to improve the sealing, realizing a so-called film-assisted molding process. The mold compound is injected into the space between the tool and the assembly, the mold cavity, such that the top surface of the emitter and the transparent structure remain exposed. The mold compound then fills the gap between these components and is cured before the individual sensor units are singulated.

Further embodiments of the manufacturing method according to the improved concept become apparent to a person skilled in the art from the embodiments of the semiconductor sensor device described above.

The following description of figures of exemplary embodiments may further illustrate and explain aspects of the improved concept. Components and parts with the same structure and the same effect, respectively, appear with equivalent reference symbols. Insofar as components and parts correspond to one another in terms of their function in different figures, the description thereof is not necessarily repeated for each of the following figures.

In the figures:

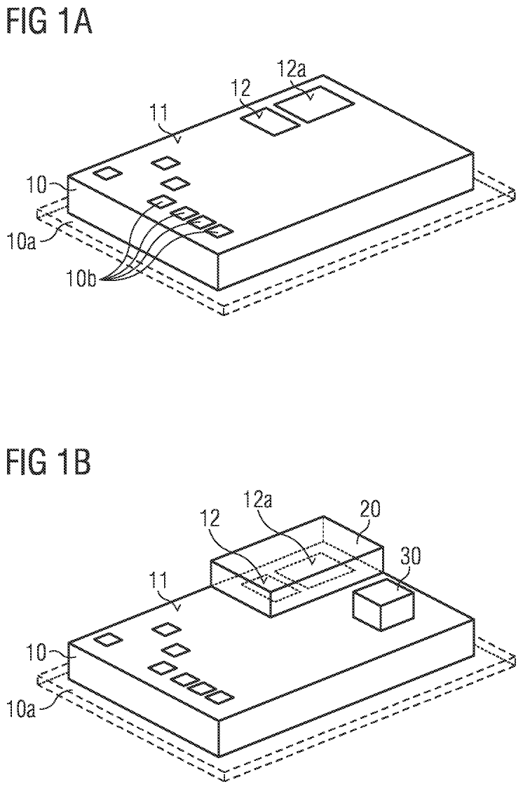

FIGS. 1A to 1C show intermediate products of an exemplary embodiment of a semiconductor sensing device according to the improved concept;

FIG. 1D shows an exemplary embodiment of a semiconductor sensing device according to the improved concept;

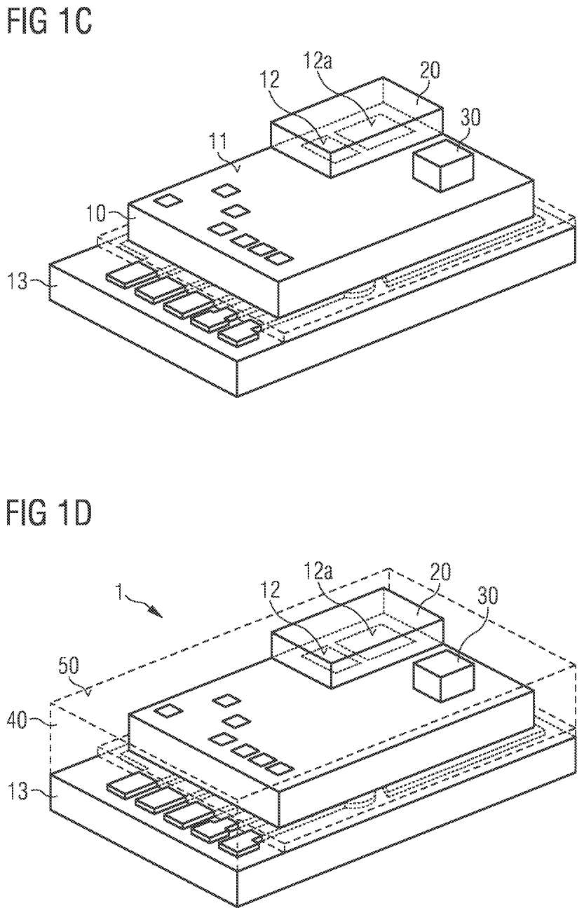

FIG. 2 shows a further exemplary embodiment of a semiconductor sensing device according to the improved concept; and

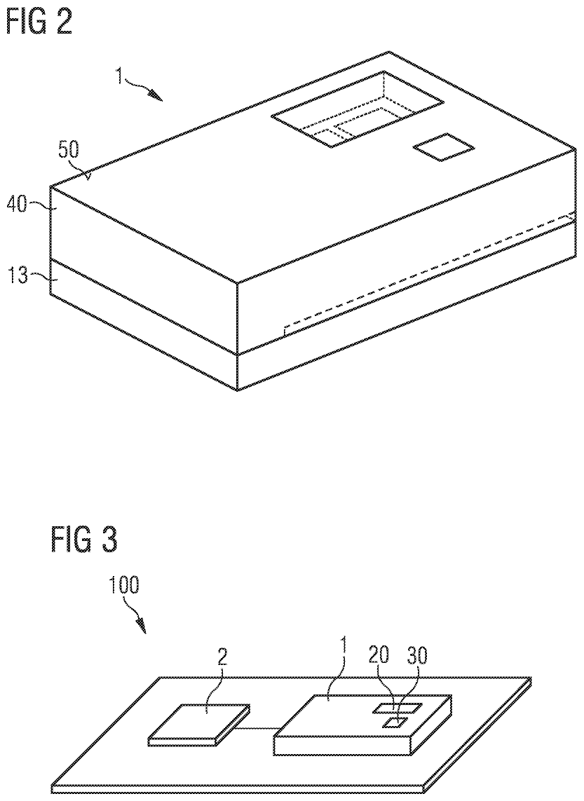

FIG. 3 shows an embodiment of a proximity sensor assembly comprising a semiconductor sensing device according to the improved concept.

FIG. 1A shows an intermediate product of a semiconductor sensing device 1 according to the improved concept. At this stage of the manufacturing process, an integrated circuit body 10 is provided. The integrated circuit body 10 comprises integrated circuit elements 10b arranged on or within a main surface 11 of the integrated circuit body 10. For example, the integrated circuit elements 10b include active and passive circuitry for operating an optical sensor device. In particular, the integrated circuit body 10 includes a photosensitive element such as an integrated photodiode having a sensing surface 12 that is configured to absorb photons and generate an electrical photo signal based on the absorbed photons. The concept of integrated photodiodes with a sensing surface is a well-known concept in the field of sensors and is not further detailed in this disclosure. The integrated circuit elements 10b can further include conductive paths on or within the main surface 11 for electrically interconnecting components of the integrated circuit. The integrated circuit elements 10b further include means for contacting an emitter assembly 30, e.g. a contact pad.

In the embodiment shown, the intermediate product further includes a further sensing surface 12a. For example, the further sensing surface 12a is configured to absorb photons within a wavelength range that is different from a sensitivity range of the first sensing surface 12. For example, the further sensing surface 12a is configured to be sensitive within the visible domain, while the first sensing surface 12 is configured to be sensitive in the infrared domain, e.g. at a wavelength of 840 nm and/or 930 nm.

In the embodiment shown, the integrated circuit body 10 is arranged on an integrated circuit substrate 10a. For example, the integrated circuit substrate 10a is a handling substrate such as a silicon chip or wafer, on which the integrated circuit body 10 is manufactured.

FIG. 1B shows a further intermediate product of the semiconductor sensing device 1 of FIG. 1A, in which a transparent structure 20 and an emitter assembly 30 is arranged.

The transparent structure 20 can be a glass boy, for instance a borosilicate 3.3 glass body that is transparent at a sensing wavelength of the sensing surface 12 and the optional further sensing surface 12a. For example, the transparent structure 20 is transparent in the visible and in the infrared domain. The transparent structure 20 is arranged on the main surface 11 of the integrated circuit body 10. In particular, the transparent structure 20 is arranged in a manner that at least the sensing surface 12 and the further sensing surface 12a is covered. The transparent structure 20 is in contact with the main surface, either in direct contact or via an interlayer such as an adhesive that is likewise transparent within the discussed wavelength range or ranges.

For further limiting or defining a capturing range of the sensing surface 12, the transparent structure may be coated at its top surface facing away from the sensing surface 12 and/or at its bottom surface facing the sensing surface 12 for forming an optical filter such as an interference filter or a bandpass filter. A transmissivity of the filter can be wavelength dependent and/or angle dependent such that only light with a certain wavelength that impinges on the top surface of the transparent structure 20 in a substantially orthogonal manner enters the transparent structure 20 and is passed to the sensing surface 12.

The emitter assembly 30 is arranged on the main surface 11 of the integrated circuit body 10 in a manner that an electrical connection is established between the main surface 11 and an emitter of the emitter assembly 30. For example, the emitter assembly 30 is a die that is arranged on an electrical contact pad, e.g. a bonding or solder pad, of the integrated circuit body 10. The emitter assembly 30 includes an emitter that is operable to emit light at a wavelength or wavelength range that corresponds to a sensitivity of the sensing surface 12. For example, the emitter assembly 30 comprises a vertical-cavity surface-emitting laser, VCSEL, and/or a light-emitting diode, LED. For example, the emitter of the emitter assembly is operable to emit light in the infrared domain, e.g. at 840 nm and/or at 930 nm.

The transparent structure 20 and the emitter assembly are dimensioned such that their top surfaces form a common plane. Preferably, this common plane is parallel to the main surface 11. In other words, a heights of the transparent structure 20 and the emitter assembly above the main surface 11 is equal.

A distance between the transparent structure 20 and the emitter assembly 30 is less than 500 μm, in particular less than 300 μm. For example, a gap in between the transparent structure 20 and the emitter assembly 30 is in the order of 200 μm. A footprint of the emitter assembly 30 is smaller than 40,000 μm². For example, the emitter assembly 30 has a rectangular or square footprint of 20 μm edge length. Likewise, a footprint of the sensing surface 12 is smaller than 40,000 μm².

FIG. 1C shows a further intermediate product of the semiconductor sensing device 1 of FIG. 1B, in which the integrated circuit body 10 is arranged onto a substrate body 13, either directly or via the optional integrated circuit substrate 10a. The substrate body 13 is for example a substrate or a leadframe that can comprise additional circuitry for operating the sensor device. In this case, also electrical connections are established between the integrated circuit body 10 and the substrate body 13. For example, the substrate body 13 is wirebonded to the integrated circuit body 10.

The substrate body 13 determines a footprint of the semiconductor sensor device 1, which is smaller than 3 mm², in particular smaller than 2 mm². For example, the substrate body 13 has a rectangular footprint with respective edge lengths of 1 mm and 2 mm at most.

FIG. 1D shows a finalized exemplary embodiment of a semiconductor sensing device 1 that is based on the intermediate products of FIGS. 1A to 1C. For finalization, a molding process is performed. For example, a float mold tool is brought in contact with the top surface of the emitter assembly 30 and the transparent structure 20. A compliant polymer film on the tool can be used to improve the sealing according to a film assisted molding process. The mold compound is injected in the space between the tool and the assembly, such the top surfaces of the emitter assembly 30 and the transparent structure 20 remain exposed. The mold compound, e.g. an epoxy, fills the gap between these components. The mold compound is eventually cured and forms an opaque body 40. A top surface 50 of said opaque body 40 together with top surfaces of the transparent structure 20 and the emitter assembly 30 form a common plane. In other words, the opaque body 40 covers the entire surface of the integrated circuit body 10, and optionally of the entire substrate body 13, except for where the transparent structure 20 and the emitter assembly 30 are arranged.

In FIG. 1D, the opaque body 40 is illustrated as being transparent for illustration purposes only.

FIG. 2 shows the exemplary embodiment of the semiconductor sensing device 1 of FIG. 1D, in which the opacity of the opaque body 40 is apparent. In particular, the opaque body 40 prevents a direct path from the emitter assembly 30 to the sensing surfaces 12, 12A as well as to the transparent structure 20, hence efficiently preventing optical cross-talk, which poses a standing problem for existing solutions.

FIG. 3 shows an exemplary embodiment of a proximity sensor assembly 100 comprising a semiconductor sensor device 1 according to one of the embodiments described above. Therein, the photosensitive element with its sensing surface 12 covered by the transparent structure 20 is configured to capture light that is emitted from the emitter assembly 30 and reflected from an object located in a proximity of the proximity sensor, e.g. a body part of a user.

The proximity sensor assembly 100 further comprises a processing unit 2 that is coupled to the sensing device 1 and is configured to operate said sensing device 1. For example, the processing unit 2 is configured to activate an emission of the emitter assembly 30 and to readout a photo signal generated by the photosensitive element via absorption of photons on or within the sensing surface 12. The sensing device 1 and the processing unit 2 can be arranged on a common carrier, e.g. a chip substrate.

Such a proximity sensor assembly 100 due to its small form factor can be conveniently employed in wearable devices such as smartwatches or earphones for determining whether the device is worn or not, for instance. However, a placement in a mobile phone or smartphone can be advantageous as well, as the typical bezel of a phone in this case can be significantly reduced in terms of the size.

It is further pointed out that a semiconductor sensor device 1 according to the improved concept is not limited to applications for proximity sensing. The improved concept can likewise be implemented in all types of optical sensing devices having an emitter and receiver for efficiently reducing cross-talk while maintaining a small form factor, i.e. footprint. For example, an alternative application is a module for facial or fingerprint recognition, in which an illuminating light source, such as a dot projector acts as emitter and an image sensor is employed as photosensitive element.

The embodiments of the semiconductor sensor device and the manufacturing method herein have been discussed for the purpose of familiarizing the reader with novel aspects of the idea. Although preferred embodiments have been shown and described, many changes, modifications, equivalents and substitutions of the disclosed concepts may be made by one having skill in the art without unnecessarily departing from the scope of the claims.

In particular, the disclosure is not limited to the disclosed embodiments, and gives examples of as many alternatives as possible for the features included in the embodiments discussed. However, it is intended that any modifications, equivalents and substitutions of the disclosed concepts be included within the scope of the claims which are appended hereto.

Features recited in separate dependent claims may be advantageously combined. Moreover, reference signs used in the claims are not limited to be construed as limiting the scope of the claims.

Furthermore, as used herein, the term “comprising” does not exclude other elements. In addition, as used herein, the article “a” is intended to include one or more than one component or element, and is not limited to be construed as meaning only one.

Unless otherwise expressly stated, it is in no way intended that any method set forth herein be construed as requiring that its steps be performed in a specific order. Accordingly, where a method claim does not actually recite an order to be followed by its steps or it is not otherwise specifically stated in the claims or descriptions that the steps are to be limited to a specific order, it is in no way intended that any particular order be inferred.

This patent application claims the priority of U.S. patent application 63/195,458 and German patent application 10 2021 115 461.8, the disclosure content of which is hereby incorporated by reference.

### REFERENCE NUMERALS

1 semiconductor sensor device
2 processing unit
10 integrated circuit body
10a integrated circuit substrate
10b integrated circuit element
11 main surface
12, 12a sensing surface
13 substrate body
20 transparent structure
30 emitter assembly
40 opaque body
50 common plane
100 proximity sensor assembly

1. A semiconductor sensor device, comprising:
an integrated circuit body having a main surface;
a photosensitive element arranged on the main surface, the photosensitive element having a sensing surface;
a transparent structure arranged on the sensing surface;
an emitter assembly arranged on the main surface at a distance from the photosensitive element; and
an opaque body arranged on a portion of the main surface that is free of the sensing surface and the emitter assembly,
wherein top surfaces of the transparent structure, the emitter assembly and the opaque body form a common plane, and
wherein the transparent structure is a glass body.

2. The semiconductor sensor device according to claim 1, wherein the common plane is parallel to the main surface.

3. The semiconductor sensor device according to claim 1, wherein the opaque body covers all portions of the main surface that are free of the sensing surface and the emitter assembly.

4. The semiconductor sensor device according to claim 1, wherein the opaque body is a polymer mold compound, in particular formed from an epoxy.

5. The semiconductor sensor device according to claim 1, further comprising a substrate body or a leadframe that is bonded to a surface of the integrated circuit body opposite the main surface.

6. The semiconductor sensor device according to claim 1, wherein the emitter assembly comprises a VCSEL die having a vertical-cavity surface-emitting (VCSEL).

7. The semiconductor sensor device according to claim 6, wherein the VCSEL die comprises a backside emitting VCSEL structure.

8. The semiconductor sensor device according to claim 1, wherein the emitter assembly comprises an LED die having a light-emitting diode, LED.

9. The semiconductor sensor device according to claim 1, wherein a transparent adhesive is arranged between the photosensitive element and the transparent structure.

10. The semiconductor sensor device according to claim 1, wherein a footprint of the transparent structure covers all of the sensing surface.

11. The semiconductor sensor device according to claim 1, wherein the transparent structure is a borosilicate glass body, in particular a borosilicate glass 3.3 body.

12. The semiconductor sensor device according to claim 1, wherein the transparent structure comprises an optical filter, in particular a bandpass filter and/or an interference filter.

13. The semiconductor sensor device according to claim 1, wherein a distance between the sensing surface and the emitter assembly is less than 500 μm, in particular less than 300 μm.

14. The semiconductor sensor device according to claim 1, wherein a footprint of the emitter assembly is smaller than 40,000 μm².

15. The semiconductor sensor device according to claim 1, wherein a footprint of the sensing surface is smaller than 40,000 μm².

16. The semiconductor sensor device according to claim 1, wherein a footprint of the semiconductor sensor device is smaller than 3 mm², in particular smaller than 2 mm².

17. The semiconductor sensor device according to claim 1, further comprising a further photosensitive element arranged on the main surface at a distance from the photosensitive element, the further photosensitive element having a further sensing surface, wherein the transparent structure is arranged on the sensing surface and on the further sensing surface.

18. A proximity sensor assembly comprising a semiconductor sensor device according to claim 1, wherein the photosensitive element is configured to capture light that is emitted from the emitter assembly and reflected from an object located in a proximity of the proximity sensor.

19. A method for manufacturing a semiconductor sensor device, the method comprising
providing an integrated circuit body having a main surface;
arranging a photosensitive element with a sensing surface onto the main surface;
arranging a transparent structure on the sensing surface;
arranging an emitter assembly on the main surface at a distance from the photosensitive element; and
arranging an opaque body on a portion of the main surface that is free of the sensing surface and the emitter assembly;
wherein top surfaces of the transparent structure, the light emitter assembly and the opaque body form a common plane, and
wherein the transparent structure is a glass body.

20. The method according to claim 19, wherein
arranging the transparent structure is implemented via gluing said transparent structure to the sensing surface; and
arranging the opaque body is implemented via an injection molding process, in particular via a film assisted transfer molding process.
